(19) United States
(12) Patent Application Publication
(10) Pub. No.: US 2014/0084252 A1
(43) Pub. Date: Mar. 27, 2014

(54) DOPED GRAPHENE TRANSPARENT CONDUCTIVE ELECTRODE

(71) Applicant: INTERNATIONAL BUSINESS MACHINES CORPORATION, Armonk, NY (US)

(72) Inventors: Tze-Chiang Chen, Yorktown Heights, NY (US); James B. Hannon, Lake Lincolndale, NY (US); Ning Li, White Plains, NY (US); Satoshi Oida, Yorktown Heights, NY (US); Devendra K. Sadana, Pleasantville, NY (US); George S. Tulevski, White Plains, NY (US)

(73) Assignee: INTERNATIONAL BUSINESS MACHINES CORPORATION, Armonk, NY (US)

(21) Appl. No.: 13/626,411

(22) Filed: Sep. 25, 2012

(51) Int. Cl. H01B 5/00; H01L 51/52; H01L 51/54; B82Y 99/00

(52) U.S. Cl. 257/40; 257/79; 174/126.1; 257/E51.026; 257/E51.018; 977/734

(57) ABSTRACT

Graphene is used as a replacement for indium tin oxide as a transparent conductive electrode which can be used in an organic light emitting diode (OLED) device. Using graphene reduces the cost of manufacturing OLED devices and also makes the OLED device extremely flexible. The graphene is chemically doped so that the work function of the graphene is shifted to a higher value for better hole injection into the OLED device as compared to an OLED device containing an undoped layer of graphene. An interfacial layer comprising a conductive polymer and/or metal oxide can also be used to further reduce the remaining injection barrier.

### BACKGROUND

The present disclosure relates to a transparent conductive electrode and a method of forming the same. More particularly, the present disclosure relates to a doped graphene transparent conductive electrode, an organic light emitting diode (OLED) device containing the doped graphene transparent conductive electrode, and methods of forming the doped graphene transparent conductive electrode and the OLED device containing the same.

Organic light emitting diode device technology is emerging as a leading technology for displays and lighting. OLED displays posses key advantages including vibrant color, high contrast ratios, wide viewing angles and are flexible over conventional liquid crystal displays (LCDs). Moreover, OLED lighting is much more efficient than incandescent bulbs and has similar efficiency as the nitride based light emitting diodes (LEDs).

A typical OLED comprises a substrate which is usually made of glass or a similar transparent material. An anode layer is positioned on the substrate. The anode layer can be made of a material having a relatively high work function and is substantially transparent for visible light. A typical material for the anode layer is indium tin oxide (ITO). A layer of electroluminescent material is positioned on the anode layer, serving as the emitting layer of the OLED. Common materials for forming the emitting layer are polymers such as, for example, poly(p-phenylenvinylene) (PPV) and molecules like tris(8-oxychinolinato) aluminum (Alq₃). In the case of molecules, the emitting layer typically comprises several layers of the molecules. A cathode layer of material having a lower work function like aluminum (Al), calcium (Ca) or magnesium (Mg) is positioned on the emitting layer. During operation of the OLED, the cathode layer and the anode layer are connected to a power supply.

The basic principles of electroluminescence and, thus, of the OLED are the following: The anode layer and the cathode layer inject charge carriers, i.e., electrons and holes, into the emitting layer. In the emitting layer, the charge carriers are transported and the charge carriers of opposite charge form so called excitons, i.e., excited states. The excitons decay radiatively into the ground state by generating light. The generated light is then emitted by the OLED through the anode layer which is made of transparent material like ITO. The color of the generated light depends on the material used for the organic emitting layer.

### SUMMARY

In the present disclosure, graphene is used as a replacement for indium tin oxide as a transparent conductive electrode which can be used in an OLED device. Using graphene reduces the cost of manufacturing OLED devices and also makes the OLED device extremely flexible. The graphene used in the present disclosure is chemically doped so that the work function of the graphene is shifted to a higher value for better hole injection into the OLED device as compared to an OLED device containing an undoped layer of graphene. An interfacial layer comprising a conductive polymer and/or metal oxide can also be used to further reduce the remaining injection barrier.

In one aspect of the present disclosure, a transparent conductive electrode is provided that can be used as an electrode of an OLED. The transparent conductive electrode of the present disclosure includes a layer of graphene doped with a single electron oxidant.

In another aspect of the present disclosure, an OLED device is provided that includes a substrate; a layer of doped graphene located on an exposed surface of the substrate; an optional interfacial layer located on an exposed surface of the layer of doped graphene; a layer of electroluminescent material located above the layer of doped graphene; and a layer of a cathode material located on an exposed surface of the layer of electroluminescent material.

In a further aspect of the present disclosure, a method of forming a transparent conductive electrode is provided. The method of forming the transparent conductive electrode includes providing a blanket layer of graphene; and doping the blanket layer of graphene with a single electron oxidant.

In yet another aspect of the present disclosure, a method of forming an OLED device containing a doped graphene transparent conductive electrode is provided. The method includes providing a substrate; forming a doped layer of graphene on an exposed surface of the substrate; forming an optional interfacial layer on an exposed surface of the layer of doped graphene; forming a layer of electroluminescent material above the layer of doped graphene; and forming a layer of a cathode material on an exposed surface of the layer of electroluminescent material.

### BRIEF DESCRIPTION OF THE DRAWINGS

FIG. 1 is a pictorial representation (through a cross sectional view) illustrating a substrate that can be employed in one embodiment of the present disclosure.

FIG. 2 is a pictorial representation (through a cross sectional view) illustrating the substrate of FIG. 1 after forming a layer of doped graphene on an exposed surface of the substrate.

FIG. 3 is a pictorial representation (through a cross sectional view) illustrating the structure of FIG. 2 after forming a layer of an interfacial material on an exposed surface of the layer of doped graphene.

FIG. 4A is a pictorial representation (through a cross sectional view) illustrating the structure of FIG. 2 after forming a layer of an electroluminescent material on an exposed surface of the layer of doped graphene.

FIG. 4B is a pictorial representation (through a cross sectional view) illustrating the structure of FIG. 3 after forming a layer of an electroluminescent material on an exposed surface of the layer of interfacial material.

FIG. 5A is a pictorial representation (through a cross sectional view) illustrating the structure of FIG. 4A after forming a layer of a cathode material on an exposed surface of the layer of electroluminescent material.

FIG. 5B is a pictorial representation (through a cross sectional view) illustrating the structure of FIG. 4B after forming a layer of a cathode material on an exposed surface of the layer of electroluminescent material.

### DETAILED DESCRIPTION

The present disclosure, which provides a doped graphene transparent conductive electrode and an OLED device containing the doped graphene transparent conductive electrode, and methods forming the doped graphene transparent conductive electrode and an OLED device containing the same, will now be described in greater detail by referring to the following discussion and drawings that accompany the present application.

It is noted that the drawings of the present application are provided for illustrative purposes and, as such, they are not drawn to scale. In the drawings and the description that follows, like materials are referred to by like reference numerals. For purposes of the description hereinafter, the terms “upper”, “lower”, “right”, “left”, “vertical”, “horizontal”, “top”, “bottom”, and derivatives thereof shall relate to the components, layers and/or materials as oriented in the drawing figures which accompany the present application.

In the following description, numerous specific details are set forth, such as particular structures, components, materials, dimensions, processing steps and techniques, in order to provide a thorough understanding of the present disclosure. However, it will be appreciated by one of ordinary skill in the art that the present disclosure may be practiced with viable alternative process options without these specific details. In other instances, well-known structures or processing steps have not been described in detail in order to avoid obscuring the various embodiments of the present disclosure.

In current OLED displays and lighting technologies, indium tin oxide transparent conductive electrodes are used as an anode. Such an OLED configuration has the following disadvantages. Transparent conductive electrodes containing indium tin oxide include the rare earth metal indium which is an expensive material thus increasing the cost of manufacturing indium tin oxide-containing OLED devices. Indium tin oxide-containing OLED devices easily fail after bending and are thus not suitable for flexible applications. Also, indium tin oxide is toxic and alternative materials for transparent conductive electrodes are thus needed.

In the present disclosure, the drawbacks mentioned above with respect to conventional indium tin oxide transparent conductive electrodes have been obviated by providing a graphene-containing electrode which is chemically doped so that the work function of the graphene-containing electrode is shifted to a higher value for better hole injection into the OLED device as compared to an equivalent OLED device containing an undoped layer of graphene. An interfacial layer comprising a conductive polymer and/or metal oxide can also be used to further reduce the remaining injection barrier.

Although the following description illustrates the transparent conductive electrode of the present disclosure as a component of an OLED device, the transparent conductive electrode of the present disclosure is not limited to being used in only such a device. Instead, the transparent conductive electrode of the present disclosure can be used in other types of devices such as, for example, photovoltaic devices, solar cells, flat panel displays or touch screens.

Also, although the OLED device is depicted with the transparent conductive electrode of the present disclosure as a bottom electrode of the OLED device, the present disclosure is not limited to only such an OLED device. Instead, OLED devices can be made in which the transparent conductive electrode of the present disclosure is a top electrode of the OLED device. In such an instance, the bottom electrode would include one of the cathode materials mentioned herein below.

Further, the OLED device of the present disclosure may include a p-doped carbon nanotube as a transparent conductive electrode instead of the layer of doped graphene. In such an embodiment, the p-doped carbon nanotube is made by first growing a carbon nanotube utilizing any conventional technique known to those skilled in the art and thereafter the carbon nanotube is doped with one of the single electron oxidants mentioned herein below utilizing a solution deposition process as also described herein below. In such an embodiment, the work function of the p-doped carbon nanotube is increased over a non-doped carbon nanotube, and the work function of the p-doped carbon nanotube is within substantially a same range as the Fermi level of the electroluminescent material.

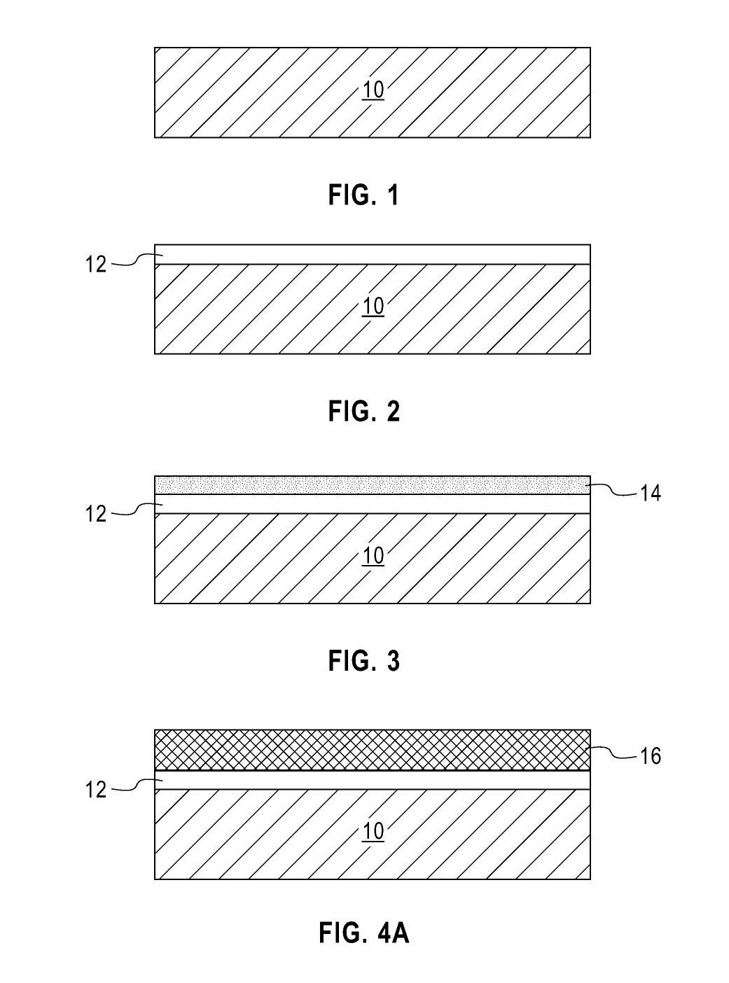

Referring to FIG. 1, there is illustrated a substrate 10 that can be employed in one embodiment of the present disclosure. The substrate 10 that can be employed in the present disclosure may be rigid or flexible and may include, for example, a semiconductor material, glass, a ceramic, tape, or a plastic. Typically, the substrate 10 that is employed in the present disclosure is a transparent substrate. In one embodiment of the present disclosure, the substrate 10 is transparent and is comprised of glass. In another embodiment of the present disclosure, the substrate 10 is transparent and is comprised of a plastic. The substrate 10 that is employed in the present disclosure may have a thickness from a few hundred microns to a few millimeters. In another embodiment, the substrate 10 that is employed may have a thickness from a few tens of microns to a few millimeters. The substrate 10 can have other thicknesses that are above and/or below the ranges mentioned above.

Referring to FIG. 2, there is illustrated the substrate 10 after forming a layer of doped graphene 12 on an exposed surface of the substrate 10. In some embodiments, and as illustrated in the drawings of the present disclosure, the layer of doped graphene 12 serves as a bottom transparent conductive electrode of an OLED device. In other embodiments, the layer of doped graphene 12 can serve as a top transparent conductive electrode of an OLED device. In yet other embodiments of the present disclosure, the layer of doped graphene 12 can serve as a transparent conductive electrode of other types of devices such as, for example, photovoltaic devices, solar cells, flat panel displays, or touch screen devices.

The layer of doped graphene 12 that is employed in the present disclosure includes graphene whose work function has been increased for better hole injection into the OLED device as compared to OLED devices containing undoped graphene. Specifically, undoped graphene has a work function that is about 4.5 eV. Doping the graphene as described herein increases the work function of the graphene to a range from greater than 4.5 eV to 5.2 eV. The increased work function of the layer of doped graphene ‘substantially’ matches the Fermi level of the layer of electroluminescent material to be subsequently formed atop the layer of doped graphene. By “substantially matches” it is meant the layer of doped graphene has a work function that is within less than 0.7 eV from the Fermi level of the layer of electroluminescent material. As such, better hole injection into the layer of electroluminescent material is provided by employing a layer of doped graphene as compared to a layer of non-doped graphene.

The layer of doped graphene 12 can be provided in the present disclosure by first depositing a blanket and non-doped layer of graphene onto a handle substrate. The handle substrate is typically comprised of a material which can catalyze the formation of graphene on a surface thereof. For example and in some embodiments of the present disclosure, the handle substrate may comprise copper or a copper foil.

The handle substrate can be formed utilizing any deposition process well known to those skilled in the art. For example, a handle substrate comprised of copper can be formed by chemical vapor deposition, plasma enhanced chemical vapor deposition, physical vapor deposition, sputtering, plating, chemical solution deposition or electroless plating. Typically, copper foils are formed by sputtering a copper foil from a copper-containing target.

In one embodiment, the handle substrate has a thickness from 7 μm to 25 μm. In another embodiment, the handle substrate has a thickness from 20 μm to 30 μm. Other thicknesses for the handle substrate that are above and/or below the thickness ranges mentioned above can also be used in the present disclosure.

After selecting the handle substrate, a blanket and non-doped graphene layer (not shown) is deposited. The term “graphene” as used throughout the present disclosure denotes a one-atom-thick planar sheet of sp²-bonded carbon atoms that are densely packed in a honeycomb crystal lattice. The graphene employed in the present disclosure has a two-dimensional (2D) hexagonal crystallographic bonding structure.

The blanket layer of graphene that can be used in the present disclosure is a contiguous layer of graphene that can be comprised of single-layer graphene (nominally 0.34 nm thick), few-layer graphene (2-10 graphene layers), multi-layer graphene (>10 graphene layers), a mixture of single-layer, few-layer, and multi-layer graphene, or any combination of graphene layers mixed with amorphous and/or disordered carbon phases that result by graphene formation at lower temperatures (between 200° C. and 900° C.). Typically, a single layer of graphene is used in the present disclosure.

The blanket layer of graphene can be formed utilizing a deposition process such as, for example, chemical vapor deposition (CVD), plasma enhanced chemical vapor deposition (PECVD), and ultraviolet (UV) assisted CVD. In one embodiment, the blanket layer of graphene is formed by CVD. In some embodiments, the deposition process that can be employed in the present disclosure in forming the blanket layer of graphene is initiated on the exposed surfaces of the handle substrate.

In one embodiment, the deposition of the blanket layer of graphene on the exposed surface of the handle substrate can be performed at a temperature up to, but not exceeding, 500° C. for PECVD. In another embodiment, the depositing (i.e., growth) of graphene occurs at a temperature from 800° C. to 1080° C. The deposition process that can be used in the present disclosure for forming the blanket layer of graphene includes utilizing any known carbon sources including, for example, benzene, propane, ethane and other hydrocarbons, and other carbon-containing gases.

In one embodiment of the present disclosure, the blanket layer of graphene can have a thickness from 0.34 nm to 0.8 nm. In another embodiment, the blanket layer of graphene can have a thickness from 0.7 nm to 3.4 nm. The blanket layer of graphene can have other thicknesses that are above the ranges mentioned above.

After depositing the blanket layer of graphene on the handle substrate, the blanket layer of graphene can then be chemically doped with a single electron oxidant utilizing a solution doping process such that one electron is transferred from the blanket layer of graphene to each molecule of the single electron oxidant. In one embodiment of the present disclosure, the single electron oxidant that can be employed is an organic single electron oxidant such as, for example, antimony compounds such as trialkyloxonium hexachlroantimonate, antimony pentachloride, nitrosonium salts (for example triethyl oxonium tetrafluoroborate), tris-(pentafluorophenyl) borane and nitrosonium cation. In one embodiment, triethyloxonium hexachloroantimonate (C₂H₅)₃O+SbCl₆ can be used as the single electron oxidant for doping a blanket layer of graphene.

In addition to organic single electron oxidants, the present disclosure can use other single electron oxidants including, for example, metal organic complexes, pi-electron acceptors, and silver salts. Examples of metal organic complexes include, but are not limited to, tris-(2,2′-bipyridyl) cobalt (III) and tris-(2,2′-bipyridyl) ruthenium (II). Examples of pi electron acceptors include, but are not limited to, tetracyanoquinodimethane, benzoquinone, tetrachlorobenzoquinone, tetrafluorobenzoquinone, tetracynaoethylene, tetrafluoro-tertracyanoquinodimethane, chloranil, tromanil and dichlorodicyanobenzoquinone. Examples of silver salts include, but are not limited to, silver fluoride, and silver trifluoroacetate.

The solution doping process that can be employed in the present disclosure is carried out with the single electron oxidant dissolved in a solvent. Suitable solvents include, for example, dichloromethane, dichloroethane, acetonitrile, chloroform and mixtures thereof. For organometallic dopants, common organic solvents like acetonitrile, tetrahydrofuran and aromatic hydrocarbons and chlorinated solvents like dichloromethane and chloroform are suitable. For inorganic salts like silver fluoride either alcohols or mixture of alcohols and water can be employed.

In one embodiment of the present disclosure, the solution doping process is performed at a temperature from 10° C. to 100° C., and the concentration of single electron oxidant in the doping solution can be from 1 mM to 20 mM. In other embodiments, the temperature can be from 30° C. to 100° C., and in still other embodiments, the temperature can be from 70° C. to 100° C.

The layer of doped graphene 12 is stable in ambient conditions. Any excess single electron oxidant on the layer of doped graphene 12 can be removed by rinsing the layer of doped graphene 12 in the same or different organic solvent used in the solution doping process. Following rinsing, the layer of doped graphene 12 can be dried under vacuum.

As stated above, the layer of doped graphene 12 has a work function that is increased relative to the same layer of graphene prior to doping. In one embodiment of the present disclosure, the layer of doped graphene 12 has a work function of greater than 4.5 eV to 5.2 eV. In another embodiment, the layer of doped graphene 12 has a work function of greater than 4.7 eV to 5.0 eV.

In accordance with the present disclosure, the layer of doped graphene 12 is a p-doped graphene layer. In some embodiments of the present disclosure, the layer of doped graphene 12 has a sheet resistance of less than 250 ohms/square. In other embodiments of the present disclosure, the layer of doped graphene 12 has a sheet resistance from 60 ohms/square to 150 ohms/square.

In some embodiments of the present disclosure, the layer of doped graphene 12 can contain from 1E11 atoms/cm² to 5E13 atoms/cm² of the single electron oxidant. In other embodiments of the present disclosure, the layer of doped graphene 12 can contain from 1E11 atoms/cm² to 5E13 atoms/cm² of the single electron oxidant.

After subjecting the blanket layer of graphene to the solution doping process mentioned above, the layer of doped graphene 12 is transferred to substrate 10 utilizing a bonding process. Bonding can be achieved at room temperature, up to about 300° C. Following bonding, the handle substrate can be removed by etching, planarization or grinding.

Although the illustrated embodiment discloses doping of the blanket layer of graphene prior to transferring to substrate 10, the present disclosure also can work when an undoped and blanket layer of graphene is first transferred to substrate 10 and then the transferred layer of graphene is subjected to the aforementioned solution doping process. It is also possible in the present disclosure to dope a blanket layer of graphene with the single electron oxidant prior to and after the transfer process.

Referring now to FIG. 3, there is illustrated the structure of FIG. 2 after forming a layer of an interfacial material 14 on an exposed surface of the layer of doped graphene 12. In some embodiments of the present disclosure, the layer of interfacial material 14 is omitted. When the layer of interfacial material 14 is employed, the layer of interfacial material can further decrease the energy barrier between the electroluminescent material to be subsequently formed and the layer of doped graphene 12. The layer of interfacial material 14 may be referred herein as a layer of a workfunction modifying material.

In one embodiment of the present disclosure, the layer of interfacial material 14 is a conductive polymer. In another embodiment of the present disclosure, the layer of interfacial material 14 is a metal oxide. In still another embodiment of the present disclosure, a stack of conductive polymers and/or metal oxides can be used in providing a multilayered interfacial structure.

When a conductive polymer is employed as the layer of interfacial material 14, the conductive polymer (which can be referred to as an intrinsically conductive polymer) includes an organic polymer that conducts electricity.

Examples of conductive polymers that can be employed in the present disclosure as the layer of interfacial material 14 include, for example, aromatic compounds containing no heteroatoms, aromatic compounds containing a nitrogen heteroatom, aromatic compounds containing a sulfur heteoatom, polymeric compounds containing double bonds and/or aromatic compounds that also contain double bonds. In some embodiments of the present disclosure, the conductive polymers that can be employed in the present disclosure as the layer of interfacial material 14 are selected from polyanilines and poly(3,4-ethylenedioxythiophene) poly(styrenesulfonate) or PEDOT:PSS for short.

The conductive polymer can be formed onto the layer of doped graphene 12 utilizing any well known deposition process including, for example, evaporation, chemical solution deposition, spin-coating, or dip coating.

When a metal oxide is employed as the layer of interfacial material 14, the metal oxide includes an element metal from Groups IIIB, IVB, VB, VIIB, VIIB, VIII or IIIA of the Periodic Table of Elements. Illustrated examples of metal oxides that can be employed in the present disclosure as the layer of interfacial material 14 include, but are not limited to, MoO₃, WO₃, V₂O₅, and Al₂O₃.

The metal oxide can be formed onto the layer of doped graphene 12 utilizing any well known deposition process including, for example, evaporation, chemical solution deposition, chemical vapor deposition, and sputtering.

In one embodiment of the present disclosure, the layer of interfacial material 14 can have a thickness from 1 nm to 70 nm. In another embodiment, the layer of interfacial material 14 can have a thickness from 15 nm to 55 nm. The layer of interfacial material 14 can have other thicknesses that are above and/or below the ranges mentioned above.

In some embodiments, the layer of interfacial material 14 can include a single layered structure. In another embodiment, the layer of interfacial material 14 can include a multilayered structure. When the layer of interfacial material 14 is a multilayered structure, the multilayered structure may include any combination of conductive polymers and/or metal oxides.

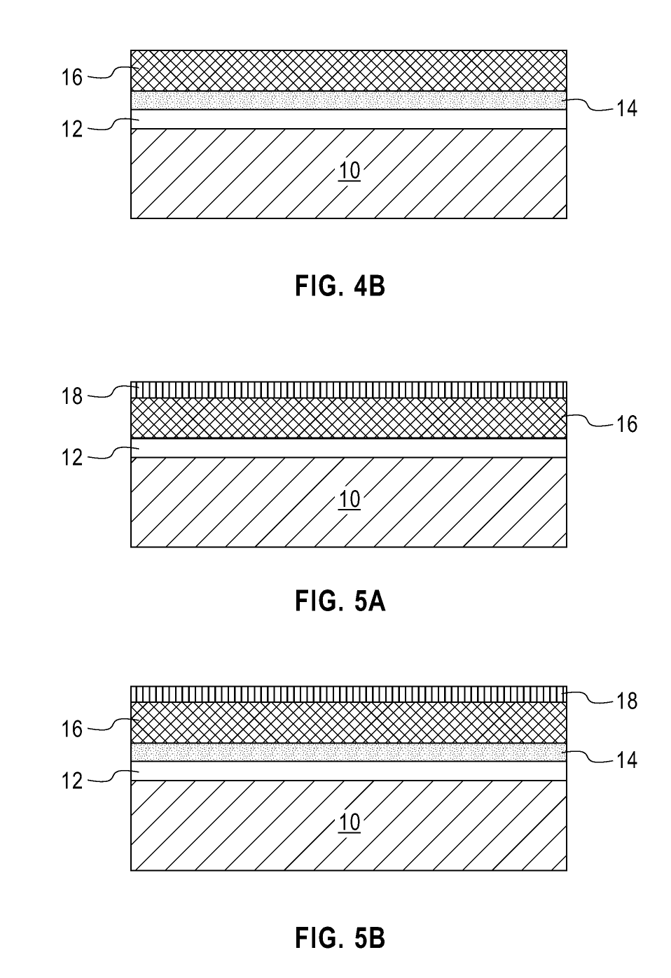

Referring to FIGS. 4A-4B, there are illustrated the structures of FIG. 2 and FIG. 3, respectively, after forming a layer of an electroluminescent material 16. Specifically, FIG. 4A illustrates the structure of FIG. 2 after forming a layer of an electroluminescent material 16 directly on an exposed surface of the layer of doped graphene 12. FIG. 4B illustrates the structure of FIG. 3 after forming a layer of an electroluminescent material 16 directly on an exposed surface of the layer of interfacial material 14.

The layer of electroluminescent material 16 that is employed in the present disclosure includes any organic material or multilayered stack of organic materials including, for example, organometallic chelates, conductive polymers, fluorescent dyes, phosphorescent dyes and conjugated dendrimers, that emits light in response to an electric current. Examples of organic materials that can be used as the electroluminescent material 16 include, but are not limited to, poly(p-phenylenvinylene) (PPV), poly(naphthalene vinylenes) (PNVs), tris(2-phenyl pyridine)iridium (Ir(ppy)₃), and tris(8-oxychinolinato) aluminum (Alq₃).

The layer of electroluminescent material 16 can be formed by conventional techniques including, for example, spin-on coating, dip coating, immersion, and chemical vapor deposition. Typically, and in one embodiment, the thickness of the layer of electroluminescent material 16 ranges from a few nm to a few hundred nm. Other thicknesses, including those above and/or below the aforementioned range can also be employed.

Referring now to FIGS. 5A-5B, there are illustrated the structures of FIG. 4A and FIG. 4B, respectively, after formation of a layer of a cathode material 18. The layer of cathode material 18 can serve as an upper electrode of the OLED of the present disclosure. Specifically, FIG. 5A and FIG. 5B illustrate the structures of FIG. 4A and FIG. 4B, respectively, after forming a layer of cathode material 18 on an exposed surface of the layer of electroluminescent material 16.

The layer of cathode material 18 that is employed in the present disclosure includes a material or a multilayered stack of materials having a lower work function than the transparent conductive electrode of doped graphene 12. In one embodiment of the present disclosure, the layer of cathode material 18 can be comprised of aluminum (Al), calcium (Ca) and/or magnesium (Mg). In some embodiments, the layer of cathode material may comprise a stack of LiF and Al.

The layer of cathode material 18 can be formed utilizing any deposition process including for example, thermal evaporation and sputtering. In some embodiments, the deposition process is performed through a shadow mask. Typically, and in one embodiment, the thickness of the layer of cathode material 18 ranges from 20 nm to 100 nm. Other thicknesses, including those above and/or below the aforementioned range can also be employed.

The transparent conductive electrode of the present disclosure which comprises the p-doped graphene layer is less toxic than a conventional ITO transparent conductive electrode. Also, transparent conductive electrodes comprised of the p-doped graphene layer are less expensive to fabricate than are their ITO counterparts. Further, transparent conductive electrodes comprised of the p-doped graphene layer are extremely flexible and thus can be used in a wide variety of display and lighting applications. Furthermore, transparent conductive electrodes comprised of the p-doped graphene layer have a higher mechanical strength than their ITO counterpart electrodes. Moreover, the transparent conductive electrodes comprised of the p-doped graphene layer are chemically stable. By “chemically stable” it is meant that the chemically doped graphene can endure processing steps which include a strong acid, base, and/or solvent, and maintain its structural integrity.

When used as a component of an OLED device, the transparent conductive electrodes comprised of the p-doped graphene layer can provide an OLED device that has, the same, or a slightly higher turn on voltage than an OLED device containing a conventional ITO electrode. In some cases, the transparent conductive electrodes comprised of the p-doped graphene layer can provide an OLED device which has a zero increase in turn on voltage as compared to an OLED device containing a conventional ITO electrode.

Also, the transparent conductive electrodes comprised of the p-doped graphene layer can provide an OLED device that has a higher quantum efficiency as compared to an OLED device containing a conventional ITO electrode. In some cases, the transparent conductive electrodes comprised of the p-doped graphene layer can provide an OLED device that has a few percent increase in quantum efficiency as compared to an OLED device containing a conventional ITO electrode. The external quantum efficiency without any out-coupling scheme is more than 20%.

Similar results as mentioned above in respect to the p-doped graphene layer can be obtained using a doped carbon nanotube layer as the transparent conductive electrode of an OLED device.

While the present disclosure has been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

1-9. (canceled)

10. An organic light emitting diode (OLED) device comprising:
a substrate;
a planar sheet of doped graphene located on an exposed surface of the substrate;
an interfacial layer located directly on an exposed surface of the planar sheet of doped graphene, said interfacial layer is selected from the group consisting of at least one of a conductive polymer and a metal oxide selected from Groups IIIB, IVB, VB, VIB, VII or IIA of the Periodic Table of Elements;
a layer of electroluminescent material located directly on an exposed surface of said interfacial layer;
a layer of a cathode material located directly on an exposed surface of the layer of electroluminescent material.

11. The OLED device of claim 10, wherein said substrate is transparent and is comprised of glass or a plastic.

12. The OLED device of claim 10, wherein said planar sheet of doped graphene is p-doped with a single electron oxidant.

13. The OLED device of claim 12, wherein said single electron oxidant is selected from the group consisting of trialkyloxonium hexachloroantimonate, antimony pentachloride, nitrosonium salt, triethyl oxonium tetrafluoroborate, tris-(pentafluorophenyl) borane and nitrosonium cation.

14. The OLED device of claim 12, wherein said single electron oxidant is trialkyloxonium hexachloroantimonate.

15. The OLED device of claim 10, wherein said planar sheet of doped graphene has a sheet resistance of less than 250 ohms/square.

16. The OLED device of claim 10, wherein said planar sheet of doped graphene has a work function value ranging from greater than 4.5 eV to 5.2 eV.

17. The OLED device of claim 12, wherein said planar sheet of doped graphene contains from 1E11 atoms/cm² to 5E13 atoms/cm² of said single electron oxidant.

18-20. (canceled)

21. The OLED device of claim 10, wherein said layer of electroluminescent material is selected from the group consisting of poly(p-phenylenvinylene) (PPV), poly(naphthalene vinylenes) (PNVs), tris(2-phenyl pyridine)iridium (Ir(ppy)₃), and tris 8-oxychinolinato) aluminum (Alq₃).

22. The OLED device of claim 10, wherein said layer of cathode material comprises aluminum (Al), calcium (Ca), magnesium (Mg) or a combination thereof.

23. The OLED device of claim 10, wherein said layer of cathode material comprises a stack of LiF and Al.

24-25. (canceled)
